(19) United States
(12) Patent Application Publication
(10) Pub. No.: US 2025/0334819 A1
(43) Pub. Date: Oct. 30, 2025

(54) OPTICAL STRUCTURE AND MANUFACTURING METHOD THEREFOR, AND DISPLAY DEVICE

(71) Applicants: Beijing Zitiao Network Technology Co., Ltd., Beijing (CN); Lemon Inc., Grand Cayman (KY)

(72) Inventors: Shaopeng ZHU, Beijing (CN); Ziyang ZHANG, Los Angeles, CA (US); Xuan ZHONG, Beijing (CN); Wenbin BAI, Beijing (CN); Jian CHEN, Beijing (CN); Jianjun HE, Beijing (CN)

(21) Appl. No.: 19/060,548

(22) Filed: Feb. 21, 2025

(30) Foreign Application Priority Data
Apr. 24, 2024 (CN) 202410502197.2

(51) Int. Cl. G02B 27/10; H10K 59/50; H10K 59/80

(52) U.S. Cl. CPC G02B 27/1006; H10K 59/50; H10K 59/879; H10K 59/8793

(57) ABSTRACT

An optical structure and a manufacturing method therefor, and a display device. The optical structure includes a first lens, a beam splitting film, a reflective polarizing film, and a first phase retardation film. The first lens includes a first surface being a surface of the first lens on the light incident side and a second surface. The beam splitting film is located on a side of the first surface away from the second surface. The reflective polarizing film and the first phase retardation film are located on a side of the second surface away from the first surface. The optical structure further includes a polarizing composite film located on a side of the beam splitting film away from the first lens and configured to convert non-polarized light incident on the polarizing composite film into circularly polarized light and disposed on a surface of the beam splitting film.

### CROSS-REFERENCE TO RELATED APPLICATION

The present application claims priority of Chinese Patent Application No. 2024105021972, filed on Apr. 24, 2024, the disclosure of which is incorporated herein by reference in its entirety as part of the present application.

### TECHNICAL FIELD

Embodiments of the present disclosure relate to an optical structure and a manufacturing method therefor, and a display device.

### BACKGROUND

Among virtual reality (VR) and mixed Reality (MR) apparatuses, a near-eye display apparatus magnifies, through a lens, an image displayed on a display, giving people an immersive feeling.

The combination of the display and the lens is called an opto-mechanical module. Current opto-mechanical modules include a combination of a liquid crystal display (LCD) or a silicon-based organic light-emitting diode (OLED) screen and a folded optical path lens (i.e. Pancake). The opto-mechanical module achieves the effect of light and thin by regulating polarized light through special polarization optical assemblies. A small-sized (e.g., 1.3-inch) silicon-based organic light-emitting diode (OLED) screen is also called a micro organic light-emitting diode (microOLED) screen.

### SUMMARY

At least one embodiment of the present disclosure provides an optical structure having a light incident side and a light exit side, the optical structure including: a first lens including a first surface and a second surface, the first surface being a surface of the first lens on the light incident side; a beam splitting film located on a side of the first surface away from the second surface; a reflective polarizing film located on a side of the second surface away from the first surface; and a first phase retardation film located on a side of the second surface away from the first surface. The optical structure further includes a polarizing composite film, the polarizing composite film is located on a side of the beam splitting film away from the first lens and configured to convert non-polarized light incident on the polarizing composite film into circularly polarized light, and the polarizing composite film is disposed on a surface of the beam splitting film.

For example, the optical structure according to an embodiment of the present disclosure further includes: a second lens located on a side of the polarizing composite film away from the first lens. The second lens includes a third surface and a fourth surface, the third surface is closer to the polarizing composite film than the fourth surface, and the polarizing composite film is in direct contact with the third surface or the polarizing composite film is adhered to the third surface.

For example, in the optical structure according to an embodiment of the present disclosure, the beam splitting film is disposed on the first surface, the first surface includes a convex surface, and the third surface includes a concave surface.

For example, in the optical structure according to an embodiment of the present disclosure, a material of the polarizing composite film includes a liquid crystal polymer.

At least one embodiment of the present disclosure provides an optical structure having a light incident side and a light exit side, the optical structure including: a first lens; a second lens closer to the light incident side of the optical structure than the first lens; a beam splitting film located between the first lens and the second lens; a reflective polarizing film located on a side of the first lens away from the second lens; and a first phase retardation film located on the side of the first lens away from the second lens. The optical structure further includes a polarizing composite film located inside the second lens and configured to convert non-polarized light incident on the polarizing composite film into circularly polarized light.

For example, in the optical structure according to an embodiment of the present disclosure, a shape of the polarizing composite film includes a planar surface.

For example, in an optical structure according to an embodiment of the present disclosure, a surface of a side of the first lens close to the second lens includes a convex surface, the beam splitting film is disposed on the convex surface.

For example, in the optical structure according to an embodiment of the present disclosure, a material of the second lens includes a resin.

For example, the optical structure according to an embodiment of the present disclosure further includes: a first anti-reflective film disposed on a side of the polarizing composite film away from the beam splitting film, a surface of a side of the first anti-reflective film away from the polarizing composite film being directly exposed to air.

For example, in the optical structure according to an embodiment of the present disclosure, the first phase retardation film is located between the reflective polarizing film and the beam splitting film, and the reflective polarizing film is configured to reflect linearly polarized light having one characteristic and transmit linearly polarized light having another characteristic; or the first phase retardation film is located on a side of the reflective polarizing film away from the beam splitting film, and the reflective polarizing film includes a cholesteric liquid crystal reflective polarizing film.

For example, in the optical structure according to an embodiment of the present disclosure, the polarizing composite film includes: a second phase retardation film; a first linear polarizing film located on a side of the second phase retardation film away from the beam splitting film; and a third phase retardation film located on a side of the first linear polarizing film away from the second phase retardation film.

For example, the optical structure according to an embodiment of the present disclosure further includes: a second linear polarizing film located on a side of the reflective polarizing film away from the first lens.

At least one embodiment of the present disclosure provides a display device, including a display screen and the optical structure as described in any of the above embodiments, the display screen being located on the light incident side of the optical structure.

For example, in the display device according to an embodiment of the present disclosure, the display screen includes a micro organic light-emitting diode display screen.

For example, in the display device according to an embodiment of the present disclosure, a second anti-reflective film is provided on a side of the display close to the polarizing composite film, and a side of the second anti-reflective film away from the display is directly exposed to air.

At least one embodiment of the present disclosure provides a display device, including a display screen and the optical structure as described in any of the above embodiments, the display screen being located on the light incident side of the optical structure, the display screen includes a micro organic light-emitting diode display screen.

At least one embodiment of the present disclosure provides a method for manufacturing an optical structure. The optical structure has a light incident side and a light exit side, and the optical structure includes a first lens, a second lens, a beam splitting film, a reflective polarizing film, a first phase retardation film, and a polarizing composite film, a first lens includes a first surface and a second surface, the first surface being a surface of the first lens on the light incident side, a second lens is located on a side of the polarizing composite film away from the first lens, a beam splitting film is located on a side of the first surface away from the second surface; a reflective polarizing film is located on a side of the second surface away from the first surface, a first phase retardation film is located on the side of the second surface away from the first surface, the polarizing composite film is located on a side of the beam splitting film away from the first lens and configured to convert non-polarized light incident on the polarizing composite film into circularly polarized light, the polarizing composite film is disposed on a surface of the beam splitting film, the second lens comprises a third surface and a fourth surface, the third surface is closer to the polarizing composite film than the fourth surface, and the polarizing composite film is in direct contact with the third surface or the polarizing composite film is adhered to the third surface. The manufacturing method includes: providing a mold for forming the second lens; placing the polarizing composite film in the mold; casting a fluid material for forming the second lens into the mold; curing the material to integrally form the polarizing composite film and the second lens; and taking the polarizing composite film and the second lens that are formed in one piece out of the mold.

At least one embodiment of the present disclosure provides a method for manufacturing an optical structure. The optical structure has a light incident side and a light exit side, and the optical structure includes a first lens, a second lens, a beam splitting film, a reflective polarizing film, a first phase retardation film, and a polarizing composite film, the second lens being closer to the light incident side of the optical structure than the first lens, the beam splitting film being located between the first lens and the second lens, the reflective polarizing film and the first phase retardation film being both located on a side of the first lens away from the second lens, and the polarizing composite film is located inside the second lens and configured to convert non-polarized light incident on the polarizing composite film into circularly polarized light. The manufacturing method includes: providing a mold for forming the second lens; placing the polarizing composite film in the mold; casting a fluid material for forming the second lens into the mold; curing the material to integrally form the polarizing composite film and the second lens; and taking the polarizing composite film and the second lens that are formed in one piece out of the mold.

At least one embodiment of the present disclosure provides a method for manufacturing an optical structure. The optical structure has a light incident side and a light exit side, and the optical structure includes a lens, a beam splitting film, a reflective polarizing film, a first phase retardation film, and a polarizing composite film, the lens including a first surface and a second surface, the first surface being a surface of the lens on the light incident side, the beam splitting film being located on a side of the first surface away from the second surface, the reflective polarizing film and the first phase retardation film being both located on a side of the second surface away from the first surface, the polarizing composite film being configured to convert non-polarized light incident on the polarizing composite film into circularly polarized light, and a material of the polarizing composite film including a liquid crystal polymer. The manufacturing method includes: coating or vacuum-plating the polarizing composite film on a surface of a side of the beam splitting film away from the lens.

For example, in the manufacturing method according to an embodiment of the present disclosure, the polarizing composite film comprises a second phase retardation film, a first linear polarizing film and a third phase retardation film, materials of the second phase retardation film, the first linear polarizing film and the third phase retardation film are each a liquid crystal polymer, coating or vacuum-plating the polarizing composite film on the surface of the side of the beam splitting film away from the lens comprises: coating or vacuum-plating the second phase retardation film, the first linear polarizing film and the third phase retardation film in sequence on the surface of the side of the beam splitting film away from the lens.

### BRIEF DESCRIPTION OF DRAWINGS

In order to illustrate the technical solutions of the embodiments of the present disclosure more clearly, the drawings of the embodiments will be briefly introduced below. Obviously, the drawings in the following description only relate to some embodiments of the present disclosure, and are not intended to limit the present disclosure.

FIG. 1 is a schematic view of a structure of an opto-mechanical module;

FIG. 2 is a schematic cross-sectional view of an optical structure according to an embodiment of the present disclosure;

FIG. 3 is a schematic cross-sectional view of another optical structure according to an embodiment of the present disclosure;

FIG. 4 is a schematic cross-sectional view of still another optical structure according to an embodiment of the present disclosure;

FIGS. 5 to 7 are schematic views of a display device according to an embodiment of the present disclosure;

FIG. 8 is a flow chart of a method for manufacturing an optical structure according to an embodiment of the present disclosure;

FIG. 9 is a flow chart of another method for manufacturing an optical structure according to an embodiment of the present disclosure;

FIG. 10 is a flow chart of still another method for manufacturing an optical structure according to an embodiment of the present disclosure; and

FIG. 11 is a flow chart of yet another method for manufacturing an optical structure according to an embodiment of the present disclosure.

### DETAILED DESCRIPTION

In order to make the objects, technical solutions and advantages of embodiments of the present disclosure clearer, the technical solutions in the embodiments of the present disclosure will be clearly and completely described below with reference to the drawings of the embodiments of the present disclosure. Apparently, the described embodiments are some rather than all of the embodiments of the present disclosure. Based on the described embodiments of the present disclosure, all other embodiments obtained by those of ordinary skill in the art without involving any inventive effort fall within the scope of protection of the present disclosure.

Unless otherwise defined, the technical or scientific terms used in the present disclosure shall have general meanings as understood by those of ordinary skill in the art to which the present disclosure pertains. “First”, “second”, and like words used in the present disclosure do not indicate any order, quantity, or importance, but are merely used to distinguish between different components. “Include” or “comprise” or like words mean that an element or item preceding the term encompasses an element or item or its equivalent listed after the term, without excluding other elements or items. “Connect” or “connected” or like words are not limited to a physical or mechanical connection, but may include an electrical connection, whether direct or indirect.

Unless defined otherwise, the features “parallel”, “perpendicular”, “identical”, etc. used in the embodiments of the present disclosure each include the case of being strictly “parallel”, “perpendicular”, “identical”, etc., and the case of being “substantially parallel”, “substantially perpendicular”, “substantially identical”, etc. containing certain errors. For example, “substantially” may indicate that the difference between compared objects is within 10% or 5% of the average value of the compared objects. When the quantity of a component or element is not specified in the following description of the embodiments of the present disclosure, it means that the number of the component or element can be one or more, or can be understood as at least one. The phrase “at least one” means one or more, and the phrase “a plurality of” means at least two. The expression “disposed in the same layer” in the embodiments of the present disclosure refers to the relationship between a plurality of film layers formed of the same material by the same step (e.g., one-step patterning process). The term “same layer” here does not always mean that the plurality of film layers have the same thickness or the plurality of film layers have the same height in a cross-sectional view.

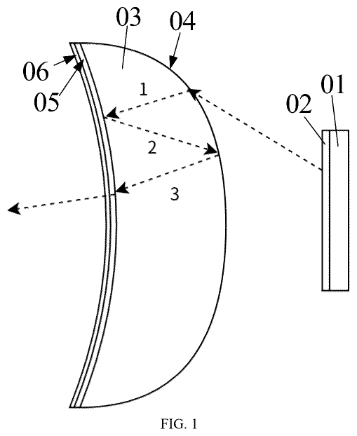

FIG. 1 is a schematic view of a structure of an opto-mechanical module. As illustrated by FIG. 1, the opto-mechanical module includes a screen 01 and an optical assembly. A circularly polarizing composite film 02 is provided on a side of the screen 01 close to the optical assembly. The screen 01 is used to generate an image, and the screen 01 emits non-polarized light without any processing. The circularly polarizing composite film 02 includes a linear polarizing film and a quarter-phase retardation film, and is attached to a light-emitting surface of the screen 01. The linear polarizing film converts the light emitted from the screen 01 into linearly polarized light, which is then converted into circularly polarized light by the quarter-phase retardation film. The optical assembly includes a set of lenses 03, a beam splitting film 04, a quarter-phase retardation film 05, and a reflective polarizing film 06. The set of lenses 03 is used to form a light focus and magnify an image, the beam splitting film 04 provides a reflective surface for a folded optical path, the quarter-phase retardation film 05 functions to change the polarization state of the light, to convert circularly polarized light into linearly polarized light, or to convert linearly polarized light into circularly polarized light, and the reflective polarizing film 06 provides another reflective surface for the folded optical path, and functions to transmit polarized light in one direction (e.g., S light) and reflect polarized light in another direction (e.g., P light).

In the opto-mechanical module described above, the key to form the folded optical path is the interconversion between the circularly polarized light and the linearly polarized light, while the ellipticity of the circularly polarized light in the folded optical path is an important physical quantity that determines the optical quality of a Pancake lens. When the ellipticity is 1, it means that polarized light is completely circularly polarized light; when the ellipticity is 0, it means that polarized light is completely linearly polarized light; when the ellipticity is between 0 and 1, it means polarized light is elliptically polarized light light, and the closer the ellipticity is to 1, the closer the elliptically polarized light is to circularly polarized light. The opto-mechanical module described above requires that the ellipticity of the circularly polarized light in the folded optical path (optical paths 1, 2, and 3 as illustrated by FIG. 1) is as close to 1 as possible. If the ellipticity is low, part of the light can not follow the optical path design, and can form stray light or ghosting, affecting the optical quality of imaging.

Therefore, it can be seen that the circularly polarizing composite film, as the initial polarizing source of the circularly polarized light, plays a decisive role in the opto-mechanical module. The circularly polarizing composite film may use a plastic functional optical film. For example, the linear polarizing film (POL) of the circularly polarizing composite film is formed by laminating a plastic film of cellulose triacetate (TAC), polymethylmethacrylate (PMMA) or cyclic olefin polymer (COP) with stretched polyvinyl alcohol (PVA) dyed with a bitropic substance. The thickness of the plastic film is about 10 to 100 microns, and the thickness of the polyvinyl alcohol is about 5 to 25 microns. For example, a quarter-phase retardation plastic film (QWP) is formed by stretching polycarbonate (PC), cyclic olefin polymer (COP) or other materials, and its thickness is about 30 to 60 microns. For example, it is also possible to use a coated quarter-phase retardation film (QWP) having a thickness of about 2 to 5 microns, which is formed by coating a liquid crystal polymer on a plastic film through liquid crystal coating and then performing transferring. These film materials are laminated by means of an optical adhesive (OCA) and a roller-pressing lamination machine to form a circularly polarizing composite film.

A common feature of the above-mentioned film materials and optical adhesives that make up the circularly polarizing composite film is that they are all mass-produced using a roll-to-roll method. The width of the rolls ranges from 1 meter to 5 meters, and the length of the rolls may be several thousand meters. The rolls are produced at an extremely high speed, which may be several to tens of meters per minute. Therefore, during the manufacturing process, even if the dust-free environment is strictly controlled, it is impossible to ensure that small particles and small defects are effectively controlled in the entire roll of tens of thousands of square meters of film material. The speed of the production process also determines that the size of the defects that can be detected and marked in production is relatively large (e.g., about 100 microns), while the commonly existing defects of a smaller size (e.g., less than 50 microns, or even 20 microns) cannot be detected. The size of the defects mentioned here is the size of the defects at the film material that are caused by particles or other problems.

Within the reach of the current film material manufacturing technology, the defect detection and control capabilities cannot be improved by technology and transformation, but have approached the physical limits of the technology. The optical film materials described above, such as the linear polarizing film (POL), the quarter-phase retardation film (QWP) and the optical adhesive (OCA), are currently mainly used in flat panel display devices. The defect tolerance of these flat panel display devices can be met by the defect control and detection capabilities of these film materials.

However, when the screen of the opto-mechanical module is evolved from a larger-size (e.g., 2.4 inches) LCD screen to a smaller-size (e.g., 1.3 inches) microOLED screen, due to the relatively small size and relatively high pixels per inch of the microOLED screen, the magnification of the optical lens developed for it is relatively high, so the tolerance to the defects of the film material arranged on the microOLED screen becomes significantly lower. For example, the size of the defects of the film material needs to be no more than 20 microns. However, due to technical limitations, the circularly polarizing composite film produced using the existing art cannot meet the requirement of such low defects., that is, the circularly polarizing composite film produced by the existing art can not meet the tolerance requirements for defects when attached to the screen. In addition, since it is impossible to first test whether the circularly polarizing composite film is qualified and then transfer it to the screen, it is needed to first bond the circularly polarizing composite film to the screen and then test whether the circularly polarizing composite film is qualified. As a result, the extremely expensive screen can be seriously affected by the low yield of the polarizing composite film, or it is needed to perform repeated reworking and film bonding until the circularly polarizing composite film is qualified. This makes it extremely difficult to realize an opto-mechanical module, which includes a microOLED screen and a Pancake lens and has a better overall quality and stronger immersive experience.

Embodiments of the present disclosure provides an optical structure. The optical structure has a light incident side and a light exit side. The optical structure includes a first lens, a beam splitting film, a reflective polarizing film, and a first phase retardation film. The first lens includes a first surface and a second surface, the first surface is a surface of the first lens on the light incident side. The beam splitting film is located on a side of the first surface away from the second surface. The reflective polarizing film is located on a side of the second surface away from the first surface. The first phase retardation film is located on a side of the second surface away from the first surface. The optical structure further includes a polarizing composite film. The polarizing composite film is located on a side of the beam splitting film away from the first lens and configured to convert non-polarized light incident on the polarizing composite film into circularly polarized light, and the polarizing composite film is disposed on a surface of the beam splitting film.

In the optical structure according to embodiments of the present disclosure, the polarizing composite film is disposed on the surface of the beam splitting film, on the one hand, the light emitted from the display screen is non-polarized light, so there is no need to consider the influence of angular distribution of the light emitted from the display screen on the polarization state or ellipticity of the light. On the other hand, after the non-polarized light is converted into circularly polarized light by the polarizing composite film, the circularly polarized light is incident on the beam splitting film, and the ellipticity of the circularly polarized light transmitted from the beam splitting film does not change substantially because the polarizing composite film is disposed on the surface of the beam splitting film, so that the circularly polarized light, the ellipticity of which is more uniform and closer to 1, can still maintain a good uniformity of ellipticity after passing through the beam splitting film.

By disposing the polarizing composite film to the optical structure, rather than to the display screen, the tolerance requirement for defect of the polarizing composite film can be reduced. In addition, by disposing the polarizing composite film to the optical structure, the optical structure with the polarizing composite film can be separately tested, so that even if the polarizing composite film has a defect that affects the display effect, the cost loss brought thereby can be greatly reduced compared to the cost loss caused by forming the polarizing composite film on the display screen, because the cost of the optical structure is much lower than the cost of the display screen.

Embodiments of the present disclosure provides another optical structure. The optical structure has a light incident side and a light exit side. The optical structure includes a first lens, a second lens, a beam splitting film, a reflective polarizing film, and a first phase retardation film. The second lens is closer to the light incident side of the optical structure than the first lens, and the beam splitting film is located between the first lens and the second lens. The reflective polarizing film is located on a side of the first lens away from the second lens. The first phase retardation film is located on a side of the first lens away from the second lens. The optical structure further includes a polarizing composite film located inside the second lens and configured to convert non-polarized light incident on the polarizing composite film into circularly polarized light.

In the optical structure according to embodiments of the present disclosure, the polarizing composite film is located inside the second lens. During the process of forming the second lens, the polarizing composite film can be formed inside the second lens at the same time, so that the process flow is simple, the process of bonding the polarizing composite film to the second lens is saved, and the problem of poor bonding caused by bonding the polarizing composite film to the second lens is avoided. Moreover, the polarizing composite film is located inside the second lens, and the second lens with the polarizing composite film can be separately detected, so that even if the polarizing composite film has a defect that affects the display effect, the cost loss brought thereby can be greatly reduced compared to the cost loss caused by forming the polarizing composite film on the display screen, because the cost of the second lens is much lower than the cost of the display screen.

By disposing the polarizing composite film inside the second lens, the polarizing composite film is no longer limited by outer surfaces of the first lens and the second lens, so that not only can the designs of the first lens, the second lens and the polarizing composite film be diversified, but also can avoid that when a surface where the polarizing composite film is located is a curved surface, the curvature of the curved surface is too large to affect the polarizing effect of the polarizing composite film.

By disposing the polarizing composite film to the optical structure, rather than to the display screen, the tolerance requirement for defect of the polarizing composite film can be reduced. In addition, light emitted from the display screen is non-polarized light, and it is thus not needed to consider the influence of the angular distribution of the light emitted from the display screen on the polarization state or ellipticity of the light.

Embodiments of the present disclosure provides a method for manufacturing an optical structure. The optical structure has a light incident side and a light exit side, and the optical structure includes a first lens, a second lens, a beam splitting film, a reflective polarizing film, a first phase retardation film, and a polarizing composite film. The second lens is closer to the light incident side of the optical structure than the first lens, the beam splitting film is located between the first lens and the second lens, the reflective polarizing film and the first phase retardation film are both located on a side of the first lens away from the second lens, and the polarizing composite film is configured to convert non-polarized light incident on the polarizing composite film into circularly polarized light. The method for manufacturing the optical structure includes: providing a mold for forming the second lens; placing the polarizing composite film in the mold; casting a fluid material for forming the second lens into the mold; curing the material to integrally form the polarizing composite film and the second lens; and taking the polarizing composite film and the second lens that are formed in one piece out of the mold.

In the manufacturing method according to embodiments of the present disclosure, during the process of forming the second lens, the polarizing composite film is formed in one piece with the second lens, so that the forming process is simple, which replaces the process of bonding the polarizing composite film to the second lens, and the difficulty and problems caused by bonding and forming the polarizing composite film on the curved surface of the second lens are avoided.

The optical structure formed by this manufacturing method includes the polarizing composite film, on the one hand, the light emitted from the display screen is non-polarized light, so there is no need to consider the influence of angular distribution of the light emitted from the display screen on the polarization state or ellipticity of the light. On the other hand, by disposing the polarizing composite film to the optical structure, rather than to the display screen, the tolerance requirement for defect of the polarizing composite film can be reduced. In addition, the polarizing composite film is formed in one piece with the second lens, so that before the second lens with the polarizing composite film is bonded to the first lens, the second lens with the polarizing composite film can be separately detected, so that even if the polarizing composite film has a defect that affects the display effect, the cost loss brought thereby is much lower than the cost loss caused by directly forming the polarizing composite film on the display screen.

Embodiments of the present disclosure provides another method for manufacturing an optical structure. The optical structure has a light incident side and a light exit side, and the optical structure includes a lens, a beam splitting film, a reflective polarizing film, a first phase retardation film, and a polarizing composite film, the lens including a first surface and a second surface, the first surface is a surface of the light incident side of the lens, the beam splitting film is located on a side of the first surface away from the second surface, the reflective polarizing film and the first phase retardation film are both located on a side of the second surface away from the first surface, the polarizing composite film is configured to convert non-polarized light incident on the polarizing composite film into circularly polarized light, and a material of the polarizing composite film including a liquid crystal polymer. The manufacturing method includes: coating or vacuum-plating the polarizing composite film on a surface of a side of the beam splitting film away from the lens.

In the manufacturing method according to embodiments of the present disclosure, the polarizing composite film is coated on the beam splitting film of the lens by a coating process or a vacuum-plating process, so that the difficulty and problems caused by bonding and forming the polarizing composite film on the curved surface of the second lens can be avoided. For example, the defect problem caused by bonding the polarizing composite film on the second lens with a relatively high curvature can be overcome.

The optical structure formed by this manufacturing method includes the polarizing composite film, on the one hand, the light emitted from the display screen is non-polarized light, so there is no need to consider the influence of angular distribution of the light emitted from the display screen on the polarization state or ellipticity of the light. In addition, the ellipticity of the circularly polarized light transmitted from the beam splitting film does not change substantially because the polarizing composite film is disposed on the surface of the beam splitting film, so that the ellipticity can still maintain a good uniformity. On the other hand, by disposing the polarizing composite film to the optical structure, rather than to the display screen, the tolerance requirement for defect of the polarizing composite film can be reduced. In addition, by coating the polarizing composite film on the beam splitting film of the lens, the lens with the polarizing composite film can be separately detected, so that even if the polarizing composite film has a defect that affects the display effect, the cost loss brought thereby is much lower than the cost loss caused by directly forming the polarizing composite film on the display screen.

The optical structure and the manufacturing method, and the display device according to the embodiments of the present disclosure will be described in detail below with reference to the drawings.

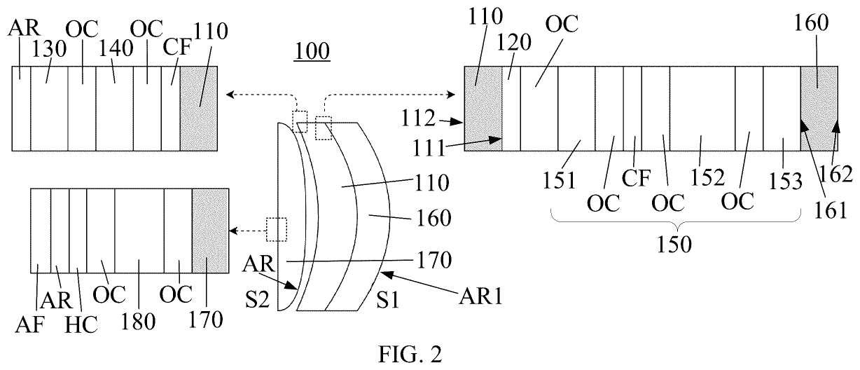

Embodiments of the present disclosure provide an optical structure. FIG. 2 is a schematic cross-sectional view of an optical structure according to an embodiment of the present disclosure. As illustrated by FIG. 2, in order to more clearly illustrate each film layer of the optical structure 100, three dashed boxes are shown enlarged. The film layers corresponding to the dashed boxes only illustrate the stacking relationship between the film layers, without involving the forms of the film layers. The optical structure 100 has a light incident side S1 and a light exit side S2. The optical structure 100 includes a first lens 110, a beam splitting film 120, a reflective polarizing film 130, and a first phase retardation film 140. The first lens 110 includes a first surface 111 and a second surface 112, the first surface 111 is a surface of the first lens 110 on the light incident side S1. The beam splitting film 120 is located on a side of the first surface 111 away from the second surface 112. The reflective polarizing film 130 is located on a side of the second surface 112 away from the first surface 111. The first phase retardation film 140 is located on the side of the second surface 112 away from the first surface 111. The optical structure 100 further includes a polarizing composite film 150. The polarizing composite film 150 is located on a side of the beam splitting film 120 away from the first lens 110 and configured to convert non-polarized light incident on the polarizing composite film 150 into circularly polarized light, and the polarizing composite film 150 is disposed on a surface of the beam splitting film 120. In the present disclosure, the light incident side S1 of the optical structure 100 refers to a side from which image light emitted from the display screen enters the optical structure 100, and the light exit side S2 refers to a side from which the image light emitted from the display screen exits after passing through the optical structure 100.

It should be noted that the polarizing composite film 150 being disposed on the surface of the beam splitting film 120 may either mean that the polarizing composite film 150 is in direct contact with the surface of the beam splitting film 120, or that the polarizing composite film 150 is disposed on the surface of the beam splitting film 120 by an adhesive or the like. The method by which the polarizing composite film 150 is disposed on the surface of the beam splitting film 120 is not limited in the embodiments of the present disclosure. For example, the polarizing composite film 150 may be formed directly on the surface of the beam splitting film 120. For example, the polarizing composite film 150 may be affixed to the surface of the beam splitting film 120 by an optical adhesive OC, in this case, an optical adhesive layer is included between the polarizing composite film 150 and the beam splitting film 120.

For an optical film material such as the beam splitting film 120 and the polarizing composite film 150, if the light incident on the optical film material is polarized light, compared with the light incident normally on the optical film material, an oblique incidence angle of an oblique incident light can affect the polarization state of the light, and further affect the ellipticity of the circularly polarized light. For example, when completely circularly polarized light is obliquely incident on the surface of the beam splitting film, both its transmitted light and reflected light can become elliptically polarized light, that is, the ellipticity decreases. In the optical structure 100 according to embodiments of the present disclosure, the polarizing composite film 150 is disposed on the surface of the beam splitting film 120, on the one hand, the light emitted from the display screen is non-polarized light, so there is no need to consider the influence of angular distribution of the light emitted from the display screen on the polarization state or ellipticity of the light. Therefore, the optical structure 110 can be adapted to more diverse display screens. For example, for a microOLED display screen having a relatively small screen size, the polarizing composite film 150 can have a better polarizing effect. On the other hand, after the non-polarized light is converted into circularly polarized light by the polarizing composite film 150, the circularly polarized light is incident on the beam splitting film 120, and the ellipticity of the circularly polarized light transmitted from the beam splitting film 120 does not change substantially because the polarizing composite film 150 is disposed on the surface of the beam splitting film 120, so that the circularly polarized light, the ellipticity of which is more uniform and closer to 1 can still maintain a good uniformity of ellipticity after passing through the beam splitting film 120. For example, when the polarizing composite film 150 is in direct contact with the beam splitting film 120, the circularly polarized light is incident on the beam splitting film 120 without passing through other optical components. For example, when the polarizing composite film 150 is affixed to the surface of the beam splitting film 120 by an optical adhesive, the circularly polarized light is incident on the beam splitting film 120 after passing through the optical adhesive between the polarizing composite film and the beam splitting film. In this case, the ellipticity of the circularly polarized light can not change substantially.

Since the optical structure 100 amplifies the light emitted by the display screen, by disposing the polarizing composite film 150 to the optical structure 100, rather than to the display screen, the tolerance requirement for defect of the polarizing composite film 150 can be reduced. For example, when the polarizing composite film 150 is disposed on a microOLED display screen, the polarizing composite film 150 needs to meet the tolerance requirement for defect where the size of the defects is 20 microns. That is, the size of the defects of the polarizing composite film 150 needs to be controlled to 20 microns. However, when the polarizing composite film 150 is disposed to the optical structure 100, the size of the defects of the polarizing composite film 150 can be relaxed to 80 microns to 100 microns, and the mass-produced polarizing composite film 150 in the existing art can meet the tolerance requirement for defect of 80 microns, but basically cannot meet the tolerance requirement for defect of 20 microns. Therefore, by disposing the polarizing composite film 150 to the optical structure 100, the tolerance requirement for defect of the polarizing composite film 150 can be reduced, so that the optical structure 100 and the display device in which it is located can be mass produced.

In addition, by disposing the polarizing composite film 150 to the optical structure 100, the optical structure 100 with the polarizing composite film 150 can be separately tested, so that even if the polarizing composite film 150 has a defect that affects the display effect, the cost loss brought thereby can be greatly reduced compared to the cost loss caused by forming the polarizing composite film 150 on the display screen, because the cost of the optical structure 100 is much lower than the cost of the display screen.

In some examples, as illustrated by FIG. 2, the optical structure 100 further includes a second lens 160. The second lens 160 is located on a side of the polarizing composite film 150 away from the first lens 110. The second lens 160 includes a third surface 161 and a fourth surface 162, the third surface 161 is closer to the polarizing composite film 150 than the fourth surface 162, and the polarizing composite film 150 is in direct contact with the third surface 161 or the polarizing composite film 150 is adhered to the third surface 161. For example, the polarizing composite film 150 may be formed in one piece with the second lens 160 by in-mold casting, in-mold injection molding, etc., and the polarizing composite film 150 is in direct contact with the third surface 161. For example, the polarizing composite film 150 may be affixed to the third surface 161 by an optical adhesive OC, and the method by which the polarizing composite film 150 is bonded to the third surface 161 is not limited in the embodiments of the present disclosure.

In this example, after the light emitted from the display screen is refracted by the second lens 160, the incident angle of the light incident to the polarizing composite film 150 can be reduced. That is, after the light obliquely incident to the second lens 160 is refracted by the second lens 160, the light incident to the polarizing composite film 150 can be made more prone to normal incidence, so that the incident angles of the light incident to different positions of the polarizing composite film 150 can be more uniform, and the ellipticity of the circularly polarized light at different positions after conversion by the polarizing composite film 150 can be more uniform and closer to 1. The ellipticity of the circularly polarized light transmitted from the beam splitting film 120 does not change substantially because the polarizing composite film 150 is disposed on the surface of the beam splitting film 120, so that the ellipticity of the circularly polarized light transmitted through the beam splitting film 120 can be made more uniform and closer to 1, thereby improving the optical performance of the optical structure 100.

In some examples, as illustrated by FIG. 2, the beam splitting film 120 is disposed on the first surface 111, the first surface 111 includes a convex surface, and the third surface 161 includes a concave surface. The first surface 111 is a convex surface, which can better form a folded optical path. For example, the beam splitting film 120 may be plated on the first surface 111.

For example, the beam splitting film 120 includes a metal layer and at least one non-metal layer disposed in a stacked arrangement. When the incident light is obliquely incident on the beam splitting film 120, for example, when the incident angle of the light incident on the beam splitting film 120 is relatively large (e.g., when the incident angle is greater than 20 degrees), a difference between a transmittance Tp of a P-polarized component of the incident light and a transmittance Ts of an S-polarized component of the incident light is not large. The beam splitting film 120 provided with the metal layer can improve the uniformity of the transmittance Tp of the P-polarized component and the transmittance Ts of the S-polarized component of the incident light compared to a dielectric beam splitting film 120 without the metal layer, so that the influence on the ellipticity of the incident light can be reduced, making the ellipticity of the incident light as close to 1 as possible.

In some examples, as illustrated by FIG. 2, the polarizing composite film 150 includes a second phase retardation film 151 and a first linear polarizing film 152. The first linear polarizing film 152 is located on a side of the second phase retardation film 151 away from the beam splitting film 120, so that non-polarized light incident on the polarizing composite film 150 is converted into circularly polarized light after passing through the first linear polarizing film 152 and the second phase retardation film 151 in sequence.

In some examples, as illustrated by FIG. 2, the polarizing composite film 150 may further include a third phase retardation film 153. The third phase retardation film 153 is located on a side of the first linear polarizing film 152 away from the second phase retardation film 151. In the display device including the optical structure 100 and the OLED display screen, the polarizing composite film 150 including the second phase retardation film 151, the first linear polarizing film 152, and the third phase retardation film 153 can also eliminate reflected light between the beam splitting film 120 and a metal cathode of the OLED display screen, further suppressing the interference of reflected light between the display screen and the beam splitting film 120. For example, as illustrated by FIG. 2, the display screen is located on a first side of the polarizing composite film 150, light incident on the polarizing composite film 150 from a second side of the polarizing composite film 150 passes through the polarizing composite film 150 and is reflected by the metal cathode of the display screen and then incident on the polarizing composite film 150, and the light reflected by the metal cathode is absorbed by the polarizing composite film 150 due to the action of the third phase retardation film 153, so that the polarizing composite film 150 can suppresses the interference of reflected light between the metal cathode of the display screen and the beam splitting film 120.

For example, a main component of the first linear polarizing film 152 that allows for polarization absorption may be an iodine-dyed stretched polyvinyl alcohol (PVA) film having a thickness of 5 to 25 microns. The PVA film may further include protective films on two sides thereof. The two protective films may be two low phase difference polymethylmethacrylate (PMMA) films, the thickness of the two PMMA films is 6 to 40 microns.

For example, the main component of the first linear polarizing film 152 that allows for polarization absorption may alternatively be a dichroic dye-dyed PVA film, or an iodine or dichroic dye-dyed liquid crystal film having a thickness of 1 to 5 microns, or orderly arranged rod-like metal nanoparticles, etc. In addition to the PMMA films, the protective films on the two sides of the main component that allows for polarization absorption may be low phase difference resin materials such as cyclic olefin polymer (COP) and cellulose triacetate (TAC). Of course, the material of the first linear polarizing film 152 is not limited in the embodiments of the present disclosure. For example, the material of the first linear polarizing film 152 may alternatively be a liquid crystal polymer.

For example, the materials of the first phase retardation film 140 and the second phase retardation film 151 may be a uniaxially stretched modified polycarbonate, or a uniaxially stretched COP, or a liquid crystal polymer formed by a coating process, or a combination of several of these materials. For example, the first phase retardation film 140 and the second phase retardation film 151 may be reverse dispersion type phase retardation films, the phase retardation of which increases with the increase of wavelength, and which can provide a constant or almost constant phase retardation over a wide spectral range, so that a stable optical performance can be maintained at different wavelengths. Of course, the materials of the first phase retardation film 140 and the second phase retardation film 151 are not limited in the embodiments of the present disclosure. For example, the materials of the first phase retardation film 140 and the second phase retardation film 151 may alternatively be a liquid crystal polymer.

In embodiments of the present disclosure, the first linear polarizing film 152 of the polarizing composite film 150 includes a direction with a highest absorption rate and a direction with a highest transmittance. The direction with the highest absorption rate is also referred to as an absorption axis, and the direction with the highest transmittance is also referred to as a transmission axis. The phase retardation film includes a direction with a highest refractive index and a direction with a lowest refractive index. The direction with the highest refractive index is also referred to as a slow axis, and the direction with the lowest refractive index is also referred to as a fast axis. An included angle between the fast axis or the slow axis of the second phase retardation film 151 and the absorption axis or the transmission axis of the first linear polarizing film 152 is 45 degrees, and an included angle between the fast axis or the slow axis of the third phase retardation film 153 and the absorption axis or the transmission axis of the first linear polarizing film 152 is 45 degrees.

In some examples, as illustrated by FIG. 2, a compensation film CF is further provided between the second phase retardation film 151 and the first linear polarizing film 152 of the polarizing composite film 150. When the incident light is oblique incident light, the compensation film CF may be used to compensate for an additional retardation in a thickness direction of the second phase retardation film 151, to avoid the adverse effect of the oblique incident light on the ellipticity, to ensure that the ellipticity is as close as possible to or equal to 1. For example, the compensation film CF may alternatively be located on a side of the second phase retardation film 151 away from the first linear polarizing film 152. This is not limited in the embodiments of the present disclosure.

For example, a compensation film CF may be also provided on a side of the third phase retardation film 153 close to or away from first linear polarizing film.

For example, a material of the compensation film CF may be a liquid crystal polymer. For example, the compensation film CF may be a liquid crystal polymer film having rod-like liquid crystals arranged in the thickness direction of the phase retardation film for compensating for the additional retardation in the thickness direction of the phase retardation film when the incident light is oblique incident light, to avoid the reduction of the ellipticity of the oblique incident light, and make the polarization ellipticity of the normal incident light and the polarization ellipticity of the oblique incident light as consistent as possible. Of course, the material of the compensation film CF is not limited in the embodiments of the present disclosure.

For example, as illustrated by FIG. 2, the first phase retardation film 140, the compensation film CF, the first linear polarizing film 152 and the second phase retardation film 151 are adhered together by the optical adhesive OC. Of course, this is not limited in the embodiments of the present disclosure.

For example, the first phase retardation film 140, the compensation film CF, the first linear polarizing film 152, the second phase retardation film 151 may alternatively be connected to each other using interlayer forces between the film layers. Thus, the first phase retardation film 140, the compensation film CF, the first linear polarizing film 152 and the second phase retardation film 151 do not need to be adhered together via the optical adhesive OC. For example, the first phase retardation film 140, the compensation film CF, the first linear polarizing film 152 and the second phase retardation film 151 may be liquid crystal polymers, so that the connection between the film layers can be realized by coating.

In some examples, as illustrated by FIG. 2, the optical structure 100 further includes a first anti-reflective film AR1. The first anti-reflective film AR1 is disposed on a side of the polarizing composite film 150 away from the beam splitting film 120, and a surface of a side of the first anti-reflective film AR1 away from the polarizing composite film 150 is directly exposed to air. The first anti-reflective film AR1 can reduce the reflection on a surface of the optical structure 100 that is directly exposed to air. In this example, the surface is located on the side of the polarizing composite film 150 away from the beam splitting film 120.

For example, as illustrated by FIG. 2, the first anti-reflective film AR1 is located on an outer surface of the second lens 160 away from the first lens 110. The first anti-reflective film AR1 can reduce the reflection on a surface of a side of the second lens 160 close to the air.

For example, the first anti-reflective film AR1 may be a composite film. The first anti-reflective film AR1 is formed by a plurality of film layers of different refractive indices stacked alternately. For example, the plurality of film layers of different refractive indices include a film layer having a first refractive index and a film layer having a second refractive index, and a plurality of film layers having the first refractive index and a plurality of film layers having the second refractive index are alternately stacked to form the first anti-reflective film AR1 to achieve the anti-reflection effect. For example, the anti-reflective film AR mentioned later may adopt such a structure, which will not be described in detail later.

For example, the first anti-reflective film AR1 may be a gradient index anti-reflective film (GRIN AR). The refractive index of the first anti-reflective film AR1 decreases in a gradient in a direction from the first lens 110 toward the second lens 160. Therefore, the first anti-reflective film AR1 can achieve a high standard of residual reflection of less than 0.05%, so that the reflection on the reflective surface on which the first anti-reflective film AR1 is formed is negligible. In this example, the reflection on the surface of the side of the second lens 160 close to the air can be made negligible. For example, the anti-reflective film AR mentioned later may adopt such a structure, which will not be described in detail later.

For example, more advanced anti-reflection coating techniques such as subwavelength structure coating (SWC), moth-eye, grass-like structure ALD hydrolysis and reactive ion deposition may be used to form the gradient index anti-reflective film (GRIN AR).

In some examples, as illustrated by FIG. 2, the first phase retardation film 140 is located between the reflective polarizing film 130 and the beam splitting film 120, and the reflective polarizing film 130 is configured to reflect linearly polarized light having one characteristic and transmit linearly polarized light having another characteristic.

For example, the circularly polarized light is converted into linearly polarized light after passing through the beam splitting film 120 and through the first phase retardation film 140. For example, the reflective polarizing film 130 includes a reflection axis and a transmission axis, and the reflective polarizing film 130 is configured to reflect linearly polarized light parallel to the reflection axis and transmit linearly polarized light parallel to the transmission axis.

In some examples, the first phase retardation film 140 may alternatively be located on a side of the reflective polarizing film 130 away from the beam splitting film 120, and the reflective polarizing film 130 includes a cholesteric liquid crystal reflective polarizing film. For example, the reflective polarizing film 130 includes a reflection handedness and a transmission handedness, and the reflective polarizing film 130 is configured to reflect circularly polarized light having the same handedness as the reflection handedness and transmit circularly polarized light having the same handedness as the transmission handedness.

In some examples, as illustrated by FIG. 2, a compensation film CF is further included on a side of the first phase retardation film 140 close to the first lens 110. The structure and beneficial technical effects of the compensation film CF are detailed above and will not be repeated here.

In some examples, as illustrated by FIG. 2, the compensation film CF, the first phase retardation film 140, and the reflective polarizing film 130 are adhered to each other by an optical adhesive OC.

In some examples, as illustrated by FIG. 2, an anti-reflective film AR is further included on a side of the reflective polarizing film 130 away from the first phase retardation film 140. The anti-reflective film AR can reduce the reflection on the surface of the side of the reflective polarizing film 130 close to the air. For example, the anti-reflective film AR may be plated on the reflective polarizing film 130.

In some examples, as illustrated by FIG. 2, the optical structure 100 further includes a third lens 170. The third lens 170 is located on a side of the first lens 110 away from the second lens 160, and a second linear polarizing film 180 is provided on a side of the third lens 170 away from the first lens 110. The second linear polarizing film 180 can reduce the reflection of the reflective polarizing film 130 close to the light exit side S2, thereby making the optical structure 100 have a better display effect.

For example, as illustrated by FIG. 2, the second linear polarizing film 180 is affixed to the third lens 170 by an optical adhesive OC.

For example, as illustrated by FIG. 2, a hardened film HC, an anti-reflective film AR, and an anti-fouling anti-fingerprint film AF may be included on a side of the second linear polarizing film 180 away from the third lens 170, so that the reflection can be reduced and the optical structure 100 can be protected.

For example, as illustrated by FIG. 2, the hardened film HC, the anti-reflective film AR and the anti-fouling anti-fingerprint film AF are affixed to the second linear polarizing film 180 by an optical adhesive OC.

In some examples, as illustrated by FIG. 2, the third lens 170 is disposed spaced from the second lens 160, and an anti-reflective film AR is provided on a side of the third lens 170 close to the first lens 110, to reduce reflection on a surface of a side of the third lens 170 close to the air. For example, the third lens 170 and the second lens 160 may also be adhered together by an optical adhesive.

In some examples, as illustrated by FIG. 2, the beam splitting film 120 is plated on a surface of a side of the first lens 110 close to the second lens 160, the polarizing composite film 150 is disposed on a surface of a side of the second lens 160 close to the first lens 110, and the first lens 110 and the second lens 160 are then affixed to each other by an optical adhesive OC. For example, the first lens 110 and the second lens 160 may be affixed to each other via an optical resin adhesive (OCR). In this case, the beam splitting film 120 formed on the first lens 110 and the polarizing composite film 150 formed on the second lens 160 are adhered together via the optical resin adhesive.

For example, the first phase retardation film 140, the second phase retardation film 151, and the third phase retardation film 153 are all quarter-phase retardation films.

For example, the first lens 110, the second lens 160, and the third lens 170 may be optical glass or resin lenses. The materials of the lenses are not limited in the embodiments of the present disclosure. For example, the material of the first lens 110 may be a cyclic olefin copolymer (COC) material, the material of the second lens 160 may be a thermosetting acrylic material, and the material of the third lens 170 may be a PMMA material.

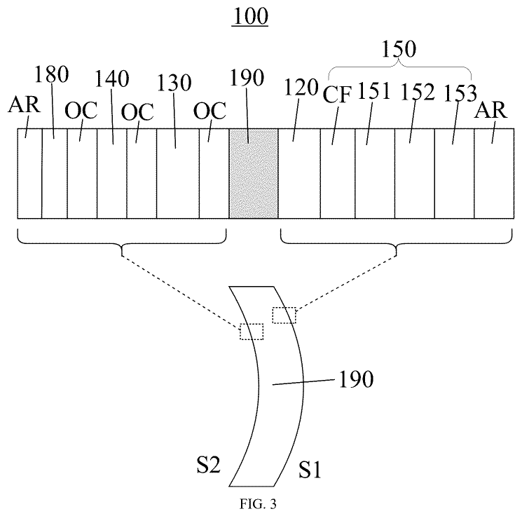

FIG. 3 is a schematic cross-sectional view of an optical structure according to an embodiment of the present disclosure. As illustrated by FIG. 3, in order to more clearly illustrate each film layer of the optical structure 100, two dashed boxes are shown enlarged. The film layers corresponding to the dashed boxes only illustrate the stacking relationship between the film layers, without involving the forms of the film layers. The optical structure 100 has a light incident side S1 and a light exit side S2. The optical structure 100 includes a lens 190, a beam splitting film 120, a reflective polarizing film 130, a first phase retardation film 140, and a polarizing composite film 150. The material of the polarizing composite film 150 includes a liquid crystal polymer. For example, when the material of the polarizing composite film 150 includes the liquid crystal polymer, the polarizing composite film 150 may be formed using a coating process. Reference can be made to the above description for the beneficial technical effects corresponding to this example, which will not be repeated here.

For example, as illustrated by FIG. 3, the polarizing composite film 150 may be in direct contact with the beam splitting film 120. For example, the polarizing composite film 150 may be coated directly on the beam splitting film 120 so that the polarizing composite film 150 is in direct contact with the beam splitting film 120. Reference can be made to the above description for the beneficial technical effects thereof, which will not be repeated here.

In some examples, as illustrated by FIG. 3, the polarizing composite film 150 includes a second phase retardation film 151 and a first linear polarizing film 152. The materials of the second phase retardation film 151 and the first linear polarizing film 152 include a liquid crystal polymer.

In some examples, as illustrated by FIG. 3, the polarizing composite film 150 may further include a third phase retardation film 153. The third phase retardation film 153 is located on a side of the first linear polarizing film 152 away from the second phase retardation film 151. The material of the third phase retardation film 153 includes a liquid crystal polymer. Therefore, the polarizing composite film 150 can suppress the interference of reflected light between the metal cathode of the display screen and the beam splitting film 120.

In some examples, as illustrated by FIG. 3, the polarizing composite film 150 further includes a compensation film CF. The compensation film CF is disposed on a side of the second phase retardation film 151 away from the first linear polarizing film 152. For example, a material of the compensation film CF may be a liquid crystal polymer.

In some examples, as illustrated by FIG. 3, an anti-reflective film AR is further provided on a side of the third phase retardation film 153 away from the first linear polarizing film 152, so that the reflection on a surface of a side of the polarizing composite film 150 close to the air can be reduced.

In some examples, as illustrated by FIG. 3, the first phase retardation film 140 may be located on a side of the reflective polarizing film 130 away from the beam splitting film 120, and the reflective polarizing film 130 includes a cholesteric liquid crystal reflective polarizing film. For example, the reflective polarizing film 130 includes a reflection handedness and a transmission handedness, and the reflective polarizing film 130 is configured to reflect circularly polarized light having the same handedness as the reflection handedness and transmit circularly polarized light having the same handedness as the transmission handedness. For example, the reflection handedness is the left handedness, the transmission handedness is the right handedness, and vice versa.

For example, the first phase retardation film 140 may alternatively be located between the reflective polarizing film 130 and the beam splitting film 120, and the reflective polarizing film 130 is configured to reflect linearly polarized light having one characteristic and transmit linearly polarized light having another characteristic.

In some examples, as illustrated by FIG. 3, a second linear polarizing film 180 is further provided on a side of the first phase retardation film 140 away from the reflective polarizing film 130. The second linear polarizing film 180 can reduce the reflection of the reflective polarizing film 130 close to the light exit side S2, thereby making the optical structure 100 have a better display effect.

For example, as illustrated by FIG. 3, a circularly polarizing film formed by the first phase retardation film 140 and the second linear polarizing film 180 located on a side of the reflective polarizing film 130 away from the lens 190 has a same transmission handedness as a transmission handedness of the reflective polarizing film 130, so that light can exit the optical structure 100 according to the optical path design.

In some examples, as illustrated by FIG. 3, an anti-reflective film AR is further provided on a side of the second linear polarizing film 180 away from the lens 190.

In some examples, the second linear polarizing film 180, the first phase retardation film 140, the reflective polarizing film 130 and the lens 190 may be adhered together by an optical adhesive OC.

For example, when the film material of the compensation film CF, the second phase retardation film 151 and the third phase retardation film 153 is a liquid crystal polymer, the film material may be formed by coating and aligning a liquid crystal polymer solution, where its formation method may be precision inkjet printing, precision electrofluid printing, etc.; and its alignment method may be rubbing alignment, photo-alignment, shear force alignment, etc. For example, an alignment layer may be coated first, and then the liquid crystal polymer is coated to align the liquid crystal polymer.

For example, the material of the first linear polarizing film 152 may also be a liquid crystal polymer, which may be coated, aligned and dyed by the methods as described above, or be formed by evaporating and photo-aligning dichroic dye liquid crystal.

For example, for the first linear polarizing film 152, the second phase retardation film 151, and the third phase retardation film 153 of the polarizing composite film 150, the orientation of the liquid crystal of each film layer needs to be controlled during a liquid crystal alignment process. For example, the orientation of the liquid crystal of each of the first linear polarizing film 152 and the second phase retardation film 151 is controlled such that the handedness of the circularly polarized light polarized by the polarizing composite film 150 is consistent with the reflection handedness of the cholesteric liquid crystal reflective polarizing film 130.

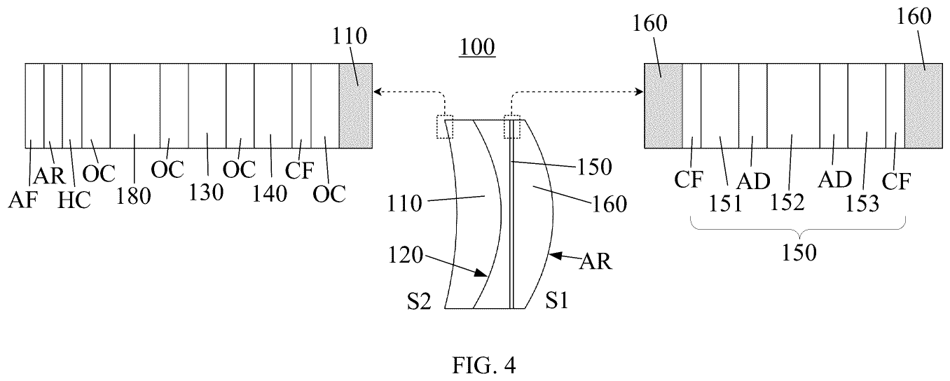

FIG. 4 is a schematic cross-sectional view of another optical structure according to an embodiment of the present disclosure. As illustrated by FIG. 4, in order to more clearly illustrate each film layer of the optical structure 100, two dashed boxes are shown enlarged. The film layers corresponding to the dashed boxes only illustrate the stacking relationship between the film layers, without involving the forms of the film layers. The optical structure 100 has a light incident side S1 and a light exit side S2. The optical structure 100 includes a first lens 110, a beam splitting film 120, a reflective polarizing film 130, and a first phase retardation film 140. The second lens 160 is closer to the light incident side S1 of the optical structure 100 than the first lens 110. The beam splitting film 120 is located between the first lens 110 and the second lens 160. The reflective polarizing film 130 is located on a side of the first lens 110 away from the second lens 160. The first phase retardation film 140 is located on the side of the first lens 110 away from the second lens 160. The optical structure 100 further includes a polarizing composite film 150. The polarizing composite film 150 is located inside the second lens 160 and configured to convert non-polarized light incident on the polarizing composite film 150 into circularly polarized light. In this embodiment, the polarizing composite film 150 is located inside the second lens 160 and is in direct contact with the second lens 160, and the polarizing composite film 150 is fixed inside the second lens 160 without any external factors such as adhesive materials.

In the optical structure 100 according to embodiments of the present disclosure, the polarizing composite film 150 is located inside the second lens 160. During the process of forming the second lens 160, the polarizing composite film 150 can be formed inside the second lens 160 at the same time, so that the process flow is simple, the process of bonding the polarizing composite film 150 to the second lens 160 is replaced, and the problem of poor bonding caused by bonding the polarizing composite film 150 to the second lens 160 is avoided. Moreover, the polarizing composite film 150 is located inside the second lens 160, and the second lens 160 with the polarizing composite film 150 can be separately detected, so that even if the polarizing composite film 150 has a defect that affects the display effect, the cost loss brought thereby can be greatly reduced compared to the cost loss caused by forming the polarizing composite film 150 on the display screen, because the cost of the second lens 160 is much lower than the cost of the display screen.

By disposing the polarizing composite film 150 inside the second lens 160, the polarizing composite film 150 is no longer limited by the outer surfaces of the first lens 110 and the second lens 160. For example, when the curvature of the outer surface of the second lens 160 is relatively large, a shape of the polarizing composite film 150 may be a planar surface or a curved surface with a small curvature. Therefore, the designs of the first lens 110, the second lens 160 and the polarizing composite film 150 are diversified, and when the shape of the polarizing composite film is a curved surface, the polarizing effect of the polarizing composite film can also be prevented from being affected by the excessive curvature of the curved surface.

By disposing the polarizing composite film 150 to the optical structure 100, the tolerance requirement for defect of the polarizing composite film 150 can be reduced, so that the optical structure 100 and the display device 200 in which it is located can be mass produced. Reference can be made to the above description for the detailed description, which will not be repeated here. In addition, light emitted from the display screen is non-polarized light, and it is thus not necessary to consider the influence of the angular distribution of the light emitted from the display screen on the polarization state or ellipticity of the light. For example, for a microOLED display screen having a smaller screen size, the polarizing composite film 150 can have a better polarizing effect.

In some examples, as illustrated by FIG. 4, a shape of the polarizing composite film 150 includes a planar surface. When the polarizing composite film 150 is bonded to a curved surface, the polarizing composite film 150 may not be completely bonded to the curved surface, and the shape of the polarizing composite film 150 bonded to the curved surface is a curved surface. Both of these can affect the performance of the polarizing composite film 150 and the optical structure 100. The performance of the polarizing composite film 150 in the form of the planar surface is superior to that of the polarizing composite film 150 in the form of the curved surface, and the formation process of the polarizing composite film 150 in the form of the planar surface is simpler and has a relatively high yield.

In some examples, as illustrated by FIG. 4, a surface of a side of the first lens 110 close to the second lens 160 includes a convex surface on which the beam splitting film 120 is disposed. The first surface 111 is a convex surface, which can better form a folded optical path, and since the polarizing composite film 150 is formed inside the second lens 160, the polarizing composite film 150 is not limited by the convex surface of the first surface 111. Therefore, the convex surface of the first surface 111 can be designed according to design requirements.

In some examples, as illustrated by FIG. 4, a material of the second lens 160 includes a resin. For example, prior to forming the second lens 160 by in-mold casting or in-mold injection molding, the polarizing composite film 150 may be placed in the mold, so that the polarizing composite film 150 may be formed inside the second lens 160.

In some examples, as illustrated by FIG. 4, the polarizing composite film 150 includes a second phase retardation film 151 and a first linear polarizing film 152. For example, the polarizing composite film 150 may further include a third phase retardation film 153 so that the polarizing composite film 150 can suppress the interference of reflected light between the metal cathode of the display screen and the beam splitting film. The detailed description can be found in the foregoing and will not be repeated here.

In some examples, as illustrated by FIG. 4, a compensation film CF is directly formed on a side of the second phase retardation film 151 of the polarizing composite film 150 away from the first linear polarizing film 152. For example, a compensation film CF is directly formed on a side of the third phase retardation film 153 of the polarizing composite film 150 away from the first linear polarizing film 152. For example, the second phase retardation film 151 and the third phase retardation film 153 located on two sides of the first linear polarizing film 152 can protect the first linear polarizing film 152. For example, the second phase retardation film 151 and the third phase retardation film 153 may be connected to the first linear polarizing film 152 via an adhesive AD. For example, the first linear polarizing film 152 may be a PVA linear polarizing film. Of course, this is not limited in the embodiments of the present disclosure.

In some examples, as illustrated by FIG. 4, the optical structure 100 further includes an anti-reflective film AR. The anti-reflective film AR is disposed on a side of the polarizing composite film 150 away from the beam splitting film 120, and a surface of a side of the anti-reflective film AR away from the polarizing composite film 150 is directly exposed to air. The anti-reflective film AR can reduce the reflection on a surface of the optical structure 100 that is directly exposed to air. The surface is located on the side of the polarizing composite film 150 away from the beam splitting film 120.

For example, as illustrated by FIG. 4, the anti-reflective film AR is located on an outer surface of the second lens 160 away from the first lens 110. The anti-reflective film AR can reduce the reflection on the surface of a side of the second lens 160 close to the air.

In some examples, as illustrated by FIG. 4, the first phase retardation film 140 is located between the reflective polarizing film 130 and the beam splitting film 120, and the reflective polarizing film 130 is configured to reflect linearly polarized light having one characteristic and transmit linearly polarized light having another characteristic.

Of course, this is not limited in the embodiments of the present disclosure. The first phase retardation film 140 may alternatively be located on a side of the reflective polarizing film 130 away from the beam splitting film 120, and the reflective polarizing film 130 includes a cholesteric liquid crystal reflective polarizing film. The structures and functions of the reflective polarizing film 130 and the first phase retardation film 140 are detailed above and will not be repeated here.

In some examples, as illustrated by FIG. 4, a compensation film CF is further included on a side of the first phase retardation film 140 close to the first lens 110.

In some examples, as illustrated by FIG. 4, a second linear polarizing film 180 is further included on a side of reflective polarizing film 130 away from the first phase retardation film 140. The second linear polarizing film 180 can reduce the reflection of the reflective polarizing film 130 close to the light exit side S2, thereby making the optical structure 100 have a better display effect.

In some examples, as illustrated by FIG. 4, a hardened film HC, an anti-reflective film AR, and an anti-fouling anti-fingerprint film AF may be included on a side of the second linear polarizing film 180 away from the first lens 110. Therefore, the reflection can be reduced and the optical structure 100 can be protected.

In some examples, as illustrated by FIG. 4, the first lens 110, the compensation film CF, the first phase retardation film 140, the reflective polarizing film 130, the second linear polarizing film 180, and the hardened film HC may be adhered to each other by an optical adhesive OC between the film layers.

For example, the first lens 110 and the second lens 160 may be affixed to each other using an optical resin adhesive (OCR).

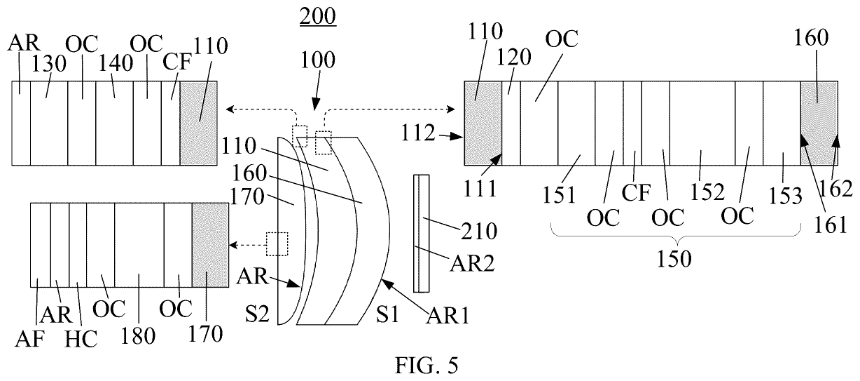

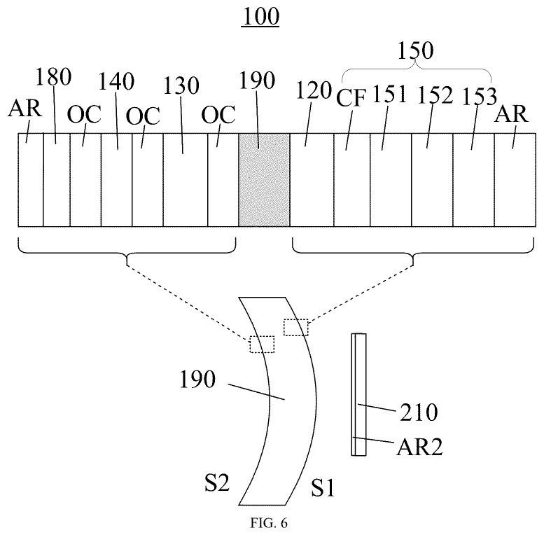

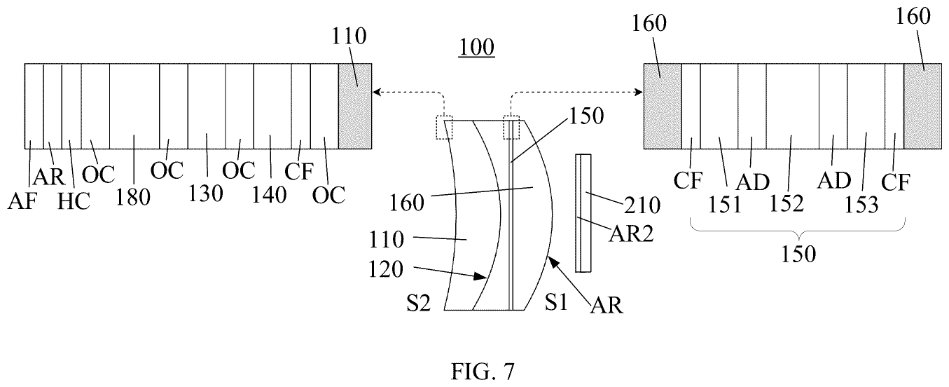

Embodiments of the present disclosure provides a display device. FIGS. 5 to 7 are schematic views of a display device according to an embodiment of the present disclosure. As illustrated by FIGS. 5 to 7, the display device 200 includes a display screen 210 and any optical structure 100 as described above. The display screen 210 is located on the light incident side S1 of the optical structure 100. Therefore, the display device 200 has the beneficial effects corresponding to the beneficial effects of the optical structure 100, which will not be repeated here.

For example, the display screen 210 may be a micro organic light-emitting diode display screen 210. The micro organic light-emitting diode display screen 210 has the advantages of better overall quality and stronger immersive experience. When the display screen 210 is a micro organic light-emitting diode display screen 210, the tolerance requirement for defect of the polarizing composite film 150 can be reduced by disposing the polarizing composite film 150 on the surface of the beam splitting film, so that the deviation or the size of the defect of the mass-produced polarizing composite film 150 can meet the requirements of the display device 200, and then the display device 200 including the micro organic light-emitting diode display screen 210 can be mass produced.

In some examples, as illustrated by FIGS. 5 to 7, a second anti-reflective film AR2 is provided on a side of the display screen 210 close to the polarizing composite film 150, and a side of the second anti-reflective film AR2 away from the display screen 210 is directly exposed to air. By providing the second anti-reflective film AR2, the reflection on a surface of a side of the display screen 210 close to the polarizing composite film 150 can be reduced. Reference can be made to the first anti-reflective film AR1 described above for the material, structure, and formation method of the second anti-reflective film AR2, which will not be repeated here.

For example, the second anti-reflective film AR2 formed on the display screen 210 may be a GRIN anti-reflective film. The GRIN anti-reflective film is formed by a process which is similar to a semiconductor process and which has a particle control level comparable to that of a process for transistors and organic light-emitting diodes in the display screen 210. The formation process of the GRIN anti-reflective film is superior to film material formation processes such as roller lamination or plate-pressing lamination, and thus can not introduce intolerable particles.

For example, the display device 200 may be a near-eye display device 200 for virtual reality (VR) or mixed reality (MR).

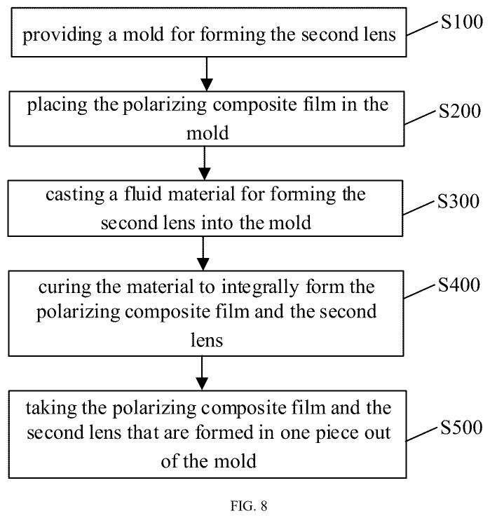

Embodiments of the present disclosure provides a method for manufacturing an optical structure. FIG. 8 is a flow chart of a method for manufacturing an optical structure according to an embodiment of the present disclosure. The optical structure has a light incident side and a light exit side, and the optical structure includes a first lens, a second lens, a beam splitting film, a reflective polarizing film, a first phase retardation film, and a polarizing composite film. The second lens is closer to the light incident side of the optical structure than the first lens, the beam splitting film is located between the first lens and the second lens, the reflective polarizing film and the first phase retardation film are both located on a side of the first lens away from the second lens, and the polarizing composite film is configured to convert non-polarized light incident on the polarizing composite film into circularly polarized light. As illustrated by FIG. 8, the method for manufacturing an optical structure includes:
providing a mold for forming the second lens;
placing the polarizing composite film in the mold;
casting a fluid material for forming the second lens into the mold;
curing the material to integrally form the polarizing composite film and the second lens; and
taking the polarizing composite film and the second lens that are formed in one piece out of the mold.

In the manufacturing method according to embodiments of the present disclosure, during the process of forming the second lens, the polarizing composite film is formed in one piece with the second lens, so that the forming process is simple, which replaces the process of bonding the polarizing composite film to the second lens, and the difficulty and problems caused by bonding and forming the polarizing composite film on the curved surface of the second lens are avoided. For example, the defect problem caused by bonding the polarizing composite film on the second lens with a relatively high curvature can be overcome.

The optical structure formed by this manufacturing method includes the polarizing composite film, on the one hand, the light emitted from the display screen is non-polarized light, so there is no need to consider the influence of angular distribution of the light emitted from the display screen on the polarization state or ellipticity of the light. On the other hand, by disposing the polarizing composite film to the optical structure, rather than to the display screen, the tolerance requirement for defect of the polarizing composite film can be reduced. In addition, the polarizing composite film is formed in one piece with the second lens, so that before the second lens with the polarizing composite film is bonded to the first lens, the second lens with the polarizing composite film can be separately detected, so that even if the polarizing composite film has a defect that affects the display effect, the cost loss brought thereby is much lower than the cost loss caused by directly forming the polarizing composite film on the display screen.

In some examples, the polarizing composite film is formed on a surface of a side of the second lens close to the first lens such that the polarizing composite film is disposed on a surface of the beam splitting film. The ellipticity of the circularly polarized light transmitted from the beam splitting film does not change substantially because the polarizing composite film is disposed on the surface of the beam splitting film, so that the circularly polarized light, the ellipticity of which is more uniform and closer to 1 can still maintain a good uniformity of ellipticity after passing through the beam splitting film.

For example, the beam splitting film is plated on a side of the first lens close to the second lens, and bonding the second lens on which the polarizing composite film is formed to the first lens so that the polarizing composite film is disposed on a surface of the beam splitting film.

For example, adhering the first lens and the second lens together using an optical adhesive. Of course, this is not limited in the embodiments of the present disclosure.

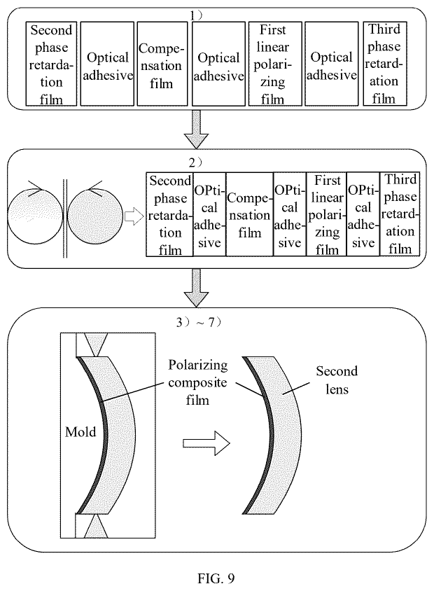

FIG. 9 is a flow chart of yet another method for manufacturing an optical structure according to an embodiment of the present disclosure. As illustrated by FIG. 9, the manufacturing method includes the following steps.
1) Providing a second phase retardation film, a compensation film, a first linear polarizing film, a third phase retardation film and an optical adhesive.

For example, the first linear polarizing film may be a composite film including two PMMA protective films and a PVA film located between the two PMMA protective films. Reference can be made to the above description for the material of each film material, which will not be limited in the present disclosure.
2) Sequentially adhering the second phase retardation film, the compensation film, the first linear polarizing film and the third phase retardation film serving as film materials via the optical adhesive, which also serves as a film material, in a roller lamination manner to form a polarizing composite film.

For example, the polarizing composite film may alternatively be formed in a screen plate lamination manner. This is not limited in the embodiments of the present disclosure.
3) Providing a mold for forming the second lens.
4) Placing the polarizing composite film in the mold.

In this example, the polarizing composite film is placed on one side of the mold such that the polarizing composite film is formed on a concave surface of the second lens. The concave surface is a surface of a side of the second lens close to the first lens.
5) Injecting a thermosetting acrylic resin monomer and a prepolymer into the mold.

For example, a UV-curable acrylic resin monomer and a prepolymer may alternatively be injected into the mold. The materials injected into the mold are not limited in the embodiments of the present disclosure.
6) Performing a thermosetting reaction to form the second lens, and integrally forming the polarizing composite film and the second lens during the process of forming the second lens.
7) Taking the polarizing composite film and the second lens that are formed in one piece out of the mold.

In some examples, the polarizing composite film is formed inside the second lens. Therefore, the polarizing composite film is no longer limited by the outer surfaces of the first lens and the second lens. For example, even if the curvature of the outer surface of the second lens is relatively large, a shape of the polarizing composite film may be a planar surface or a curved surface with a small curvature. Therefore, the designs of the first lens, the second lens and the polarizing composite film are diversified, and when the shape of the polarizing composite film is a curved surface, the polarizing effect of the polarizing composite film can also be prevented from being affected by the excessive curvature of the curved surface.

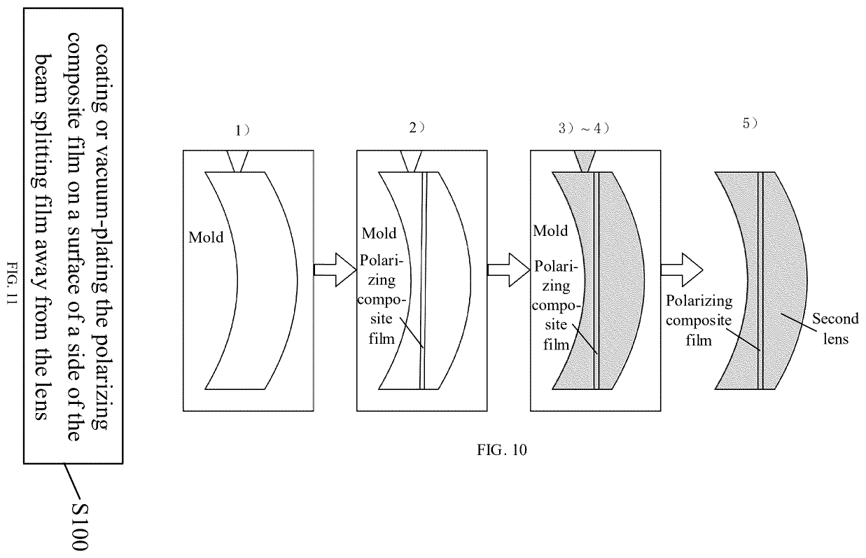

FIG. 10 is a flow chart of yet another method for manufacturing an optical structure according to an embodiment of the present disclosure. As illustrated by FIG. 10, the manufacturing method includes the following steps.
1) Providing a mold for forming the second lens.
2) Placing a polarizing composite film which has been previously compounded in the mold and fixing it.

In this example, the polarizing composite film is placed inside the mold, and two surfaces of the polarizing composite film opposite in its axial direction are both spaced from the mold so that the polarizing composite film is formed inside the second lens.
3) Injecting a UV-curable acrylic resin monomer and a prepolymer into the mold.

The materials injected into the mold are not limited in the embodiments of the present disclosure.
4) Performing a UV curing reaction to form the second lens, and integrally forming the polarizing composite film and the second lens during the process of forming the second lens.

In this example, the polarizing composite film is placed inside the mold such that the polarizing composite film is formed inside the second lens, that is, the second lens in which the polarizing composite film is embedded is formed.
5) Taking the polarizing composite film and the second lens that are formed in one piece out of the mold.

In some examples, the manufacturing method further includes forming an anti-reflective film AR1 on a side of the second lens 160 away from the first lens 110. The detailed description of the anti-anti-reflective film AR1 can be found in the foregoing and will not be repeated here.

FIG. 11 is a flow chart of yet another method for manufacturing an optical structure according to an embodiment of the present disclosure. The optical structure has a light incident side and a light exit side, and the optical structure includes a lens, a beam splitting film, a reflective polarizing film, a first phase retardation film, and a polarizing composite film, the lens includes a first surface and a second surface, the first surface is a surface of the lens on the light incident side, the beam splitting film is located on a side of the first surface away from the second surface, the reflective polarizing film and the first phase retardation film are both located on a side of the second surface away from the first surface, the polarizing composite film is configured to convert non-polarized light incident on the polarizing composite film into circularly polarized light, and a material of the polarizing composite film includes a liquid crystal polymer. As illustrated by FIG. 11, the manufacturing method includes:

Coating or vacuum-plating the polarizing composite film on a surface of a side of the beam splitting film away from the lens.

In the manufacturing method according to embodiments of the present disclosure, the polarizing composite film is coated on the beam splitting film of the lens by a coating process or a vacuum-plating process, so that difficulties and problems caused by bonding and forming the polarizing composite film on the curved surface of the second lens can be avoided. For example, the defect problem caused by bonding the polarizing composite film to the second lens with a relatively high curvature can be overcome.

The optical structure formed by this manufacturing method includes the polarizing composite film, on the one hand, the light emitted from the display screen is non-polarized light, so there is no need to consider the influence of angular distribution of the light emitted from the display screen on the polarization state or ellipticity of the light. In addition, the ellipticity of the circularly polarized light transmitted from the beam splitting film does not change substantially because the polarizing composite film is coated on the surface of the beam splitting film, so that the ellipticity can still maintain a good uniformity. On the other hand, by disposing the polarizing composite film to the optical structure, rather than to the display screen, the tolerance requirement for defect of the polarizing composite film can be reduced. In addition, by coating the polarizing composite film on the beam splitting film of the lens, the lens with the polarizing composite film can be separately detected, so that even if the polarizing composite film has a defect that affects the display effect, the cost loss brought thereby is much lower than the cost loss caused by directly forming the polarizing composite film on the display screen.

In the manufacturing method according to embodiments of the present disclosure, the polarizing composite film may be coated on the surface of the side of the beam splitting film away from the lens, or the polarizing composite film may be vacuum-plated on the surface of the side of the beam splitting film away from the lens, or at least one layer of the polarizing composite film is coated on the surface of the side of the beam splitting film away from the lens, and at least one layer of the polarizing composite film is vacuum-plated on the surface of the side of the beam splitting film away from the lens.

In some embodiments, the manufacturing method further includes: aligning the polarizing composite film. The alignment process is not limited in the embodiments of the present disclosure. For example, the alignment processes may include rubbing alignment, photo-alignment, shear force alignment, etc. For example, coating an alignment layer first, and then coating a liquid crystal polymer to align the liquid crystal polymer.

In some examples, the polarizing composite film includes a second phase retardation film, a first linear polarizing film and a third phase retardation film. The materials of the second phase retardation film, the first linear polarizing film and the third phase retardation film are each a liquid crystal polymer. Coating or vacuum-plating the polarizing composite film on the surface of the side of the beam splitting film away from the lens includes:

Coating or vacuum-plating the second phase retardation film, the first linear polarizing film and the third phase retardation film in sequence on the surface of the side of the beam splitting film away from the lens.

In some examples, the polarizing composite film further includes a compensation film located on a side of the second phase retardation film away from the first linear polarizing film. The material of the compensation film is a liquid crystal polymer. Coating or vacuum-plating the polarizing composite film on the surface of the side of the beam splitting film away from the lens includes:

Coating or vacuum-plating the compensation film, the second phase retardation film, the first linear polarizing film and the third phase retardation film in sequence on the surface of the side of the beam splitting film away from the lens.

In some embodiments, the coating process may include precision inkjet printing, precision electrofluid printing, etc. This is not limited in the embodiments of the present disclosure.

In some embodiments, a material of the first linearly polarized film includes a liquid crystal polymer, and a dyeing process is further included after coating and aligning the first linear polarizing film. Of course, this is not limited in the embodiments of the present disclosure. The first linearly polarized film may alternatively be formed by evaporating and photo-aligning dichroic dye liquid crystal.

In some examples, the first phase retardation film is located on a side of the reflective polarizing film away from the beam splitting film, and the reflective polarizing film includes a cholesteric liquid crystal reflective polarizing film. Of course, the embodiments of the present disclosure are not limited to this. For example, the first phase retardation film is located between the reflective polarizing film and the beam splitting film, and the reflective polarizing film is configured to reflect linearly polarized light having one characteristic and transmit linearly polarized light having another characteristic.

In some embodiments, during liquid crystal alignment, controlling the orientation of the liquid crystal of each of the second phase retardation film and the third phase retardation film, in particular controlling the orientation of the liquid crystal of the second phase retardation film and the orientation of the liquid crystal of the first linear polarizing film, such that the handedness of the circularly polarized light polarized by the polarizing composite film is consistent with the reflection handedness of the cholesteric liquid crystal reflective polarizing film.

The following several points need to be noted.
(1) The accompanying drawings of the embodiments of the present disclosure relate only to structures involved in the embodiments of the present disclosure, and for other structures, reference may be made to general designs.
(2) The features in the same embodiment and in different embodiments of the present disclosure may be combined with each other without conflict.

The foregoing descriptions are merely specific implementations of the present disclosure, but are not intended to limit the scope of protection of the present disclosure. Any variation or replacement readily figured out by those skilled in the art within the technical scope disclosed in the present disclosure shall fall within the scope of protection of the present disclosure. Therefore, the scope of protection of the present disclosure shall be subject to the scope of protection of the claims.

1. An optical structure, having a light incident side and a light exit side, comprising:
a first lens, comprising a first surface and a second surface, the first surface being a surface of the first lens on the light incident side;
a beam splitting film, located on a side of the first surface away from the second surface;
a reflective polarizing film, located on a side of the second surface away from the first surface; and
a first phase retardation film, located on the side of the second surface away from the first surface,
wherein the optical structure further comprises a polarizing composite film, the polarizing composite film is located on a side of the beam splitting film away from the first lens and configured to convert non-polarized light incident on the polarizing composite film into circularly polarized light, and
the polarizing composite film is disposed on a surface of the beam splitting film.

2. The optical structure according to claim 1, further comprising:
a second lens, located on a side of the polarizing composite film away from the first lens,
wherein the second lens comprises a third surface and a fourth surface, the third surface is closer to the polarizing composite film than the fourth surface, and the polarizing composite film is in direct contact with the third surface or the polarizing composite film is adhered to the third surface.

3. The optical structure according to claim 2, wherein the beam splitting film is disposed on the first surface, the first surface comprises a convex surface, and the third surface comprises a concave surface.

4. The optical structure according to claim 1, wherein a material of the polarizing composite film comprises a liquid crystal polymer.

5. An optical structure, having a light incident side and a light exit side, comprising:
a first lens;
a second lens, closer to the light incident side of the optical structure than the first lens;
a beam splitting film, located between the first lens and the second lens;
a reflective polarizing film, located on a side of the first lens away from the second lens; and
a first phase retardation film, located on the side of the first lens away from the second lens,
wherein the optical structure further comprises a polarizing composite film, the polarizing composite film is located inside the second lens and configured to convert non-polarized light incident on the polarizing composite film into circularly polarized light.

6. The optical structure according to claim 5, wherein a shape of the polarizing composite film comprises a planar surface.

7. The optical structure according to claim 5, wherein a surface of a side of the first lens close to the second lens comprises a convex surface, the beam splitting film is disposed on the convex surface.

8. The optical structure according to claim 5, wherein a material of the second lens comprises a resin.

9. The optical structure according to claim 1, further comprising:
a first anti-reflective film, disposed on a side of the polarizing composite film away from the beam splitting film, and a surface of a side of the first anti-reflective film away from the polarizing composite film being directly exposed to air.

10. The optical structure according to claim 1, wherein the first phase retardation film is located between the reflective polarizing film and the beam splitting film, and the reflective polarizing film is configured to reflect linearly polarized light having one characteristic and transmit linearly polarized light having another characteristic; or
the first phase retardation film is located on a side of the reflective polarizing film away from the beam splitting film, and the reflective polarizing film comprises a cholesteric liquid crystal reflective polarizing film.

11. The optical structure according to claim 1, wherein the polarizing composite film comprises:
a second phase retardation film;
a first linear polarizing film, located on a side of the second phase retardation film away from the beam splitting film; and
a third phase retardation film, located on a side of the first linear polarizing film away from the second phase retardation film.

12. The optical structure according to claim 1, further comprising:
a second linear polarizing film, located on a side of the reflective polarizing film away from the first lens.

13. A display device, comprising a display screen and the optical structure of claim 1, wherein the display screen is located on the light incident side of the optical structure.

14. The display device according to claim 13, wherein the display screen comprises a micro organic light-emitting diode display screen.

15. The display device according to claim 13, wherein a second anti-reflective film is provided on a side of the display screen close to the polarizing composite film, and a side of the second anti-reflective film away from the display screen is directly exposed to air.

16. A display device, comprising a display screen and the optical structure of claim 5, wherein the display screen is located on the light incident side of the optical structure, and the display screen comprises a micro organic light-emitting diode display screen.

17. A method for manufacturing the optical structure of claim 2, comprising:
providing a mold for forming the second lens;
placing the polarizing composite film in the mold;
casting a fluid material for forming the second lens into the mold;
curing the material to integrally form the polarizing composite film and the second lens; and
taking the polarizing composite film and the second lens that are formed in one piece out of the mold.

18. A method for manufacturing the optical structure of claim 5, comprising:
providing a mold for forming the second lens;
placing the polarizing composite film in the mold;
casting a fluid material for forming the second lens into the mold;
curing the material to integrally form the polarizing composite film and the second lens; and
taking the polarizing composite film and the second lens that are formed in one piece out of the mold.

19. A method for manufacturing an optical structure, wherein the optical structure has a light incident side and a light exit side, and the optical structure comprises a lens, a beam splitting film, a reflective polarizing film, a first phase retardation film, and a polarizing composite film, the lens comprises a first surface and a second surface, the first surface is a surface of the lens on the light incident side, the beam splitting film is located on a side of the first surface away from the second surface, the reflective polarizing film and the first phase retardation film are both located on a side of the second surface away from the first surface, the polarizing composite film is configured to convert non-polarized light incident on the polarizing composite film into circularly polarized light, and a material of the polarizing composite film comprises a liquid crystal polymer,
wherein the manufacturing method comprises:
coating or vacuum-plating the polarizing composite film on a surface of a side of the beam splitting film away from the lens.

20. The manufacturing method according to claim 19, wherein the polarizing composite film comprises a second phase retardation film, a first linear polarizing film and a third phase retardation film, materials of the second phase retardation film, the first linear polarizing film and the third phase retardation film are each a liquid crystal polymer, coating or vacuum-plating the polarizing composite film on the surface of the side of the beam splitting film away from the lens comprises:
coating or vacuum-plating the second phase retardation film, the first linear polarizing film and the third phase retardation film in sequence on the surface of the side of the beam splitting film away from the lens.
